(19) United States
(12) Patent Application Publication
(10) Pub. No.: US 2006/0011586 A1
(43) Pub. Date: Jan. 19, 2006

(54) Method of etching nitrides

(76) Inventor: Kevin R. Shea, Boise, ID (US)

Correspondence Address: David J. Paul;Micron Technology, Inc., MS 1-525, 8000 S. Federal Way, Boise, ID, 83716, US

(21) Appl. No.: 10/892,332

(22) Filed: Jul. 14, 2004

(51) Int. Cl. B44C 1/22; H01L 21/461

(52) U.S. Cl. 216/95; 216/83; 216/96; 216/99; 438/745; 438/757

(57) ABSTRACT

Etching chemistries for etching nitride materials selective to oxide materials and selective to resist patterning materials are disclosed along with methods of etching nitride materials, such as dielectric nitride materials and metal nitride materials. The etching chemistries and methods incorporate using an ultra-dilute (approximately 1500:1 to 2500:1) 49% hydrofluoric (HF) acid and optionally adding ozone (O₃) to the etching mixture that etches nitride materials selective to oxide materials, such as oxides doped with impurities or non-doped oxides, and resist patterning materials. The dilution of the HF acid will affect the selectivity of the etching solution (nitride material to the oxide or resist materials) and can be tailored to obtain a desired etching result.

### FIELD OF THE INVENTION

This invention relates to methods of etching materials during semiconductor fabrication processes. The invention particularly relates to etching nitride materials selective to oxide materials.

### BACKGROUND OF THE INVENTION

In semiconductor fabrication processes it is often necessary to selectively etch materials (i.e., to etch a particular material at a faster rate than another material). On common etch electivity is etching nitride materials to oxide materials. For example, during processing it may be desirable to etch silicon nitride selectively relative to a silicon oxide. In the semiconductor industry, the standard etching process utilized for etching nitrides selective to un-doped oxides is hot phosphoric acid (H₃PO₄).

For example, using hot phosphoric acid at 165° C. will render the following results: A nitride etch rate at 45 Å/min for a film deposited at 700-750° C.; an undoped oxide etch rate at 1.3 Å/min for a film deposited at any temperature; and a doped oxide etch rate, such as for borophosphosilicate glass (BPSG), phosphosilicate glass (PSG), or borosilicate glass (BSG) films, at 45 Å/min to 120 Å/min.

Typically when using hot phosphoric acid the selectivity for nitride to un-doped oxide is around 45:1, at a temperature of around 165° C. However, when using hot phosphoric acid to etch nitrides selective to doped annealed oxides, the selectivity averages around 1:1, as hot phosphoric acid will remove around 15-50 Å/minute of oxide material. Therefore, using a hot phosphoric acid results in a selectivity of about 34:1 for nitride to oxide and a selectivity of about 1:1 to 1:2 for nitride to doped oxide.

Thus, at low temperatures, phosphoric acid is unable to significantly etch silicon nitride and at high temperatures the etch rate on silicon oxide will increase while the etch rate on silicon nitride will decrease. As a result, phosphoric acid is not an ideal etching solution to remove nitride materials selective to oxide materials.

Hydrofluoric acid (HF) is another etching solution used to etch oxide and nitride materials. Unfortunately, the selectivity of HF acid for nitride to oxide is negative, which results in a faster rate of oxide removal compared to a slower rate of nitride removal.

What is needed is a method to selectively etch nitride materials relative to oxide materials (either doped or un-doped) with minimal removal of the oxide material, during the fabrication of semiconductor devices, a need of which is addressed by the following disclosure of the present invention that will become apparent to those skilled in the art.

### SUMMARY OF THE INVENTION

Exemplary implementations of the present invention include etching chemistries for etching nitride materials selective to oxide materials and selective to resist patterning materials, are disclosed along with methods of etching nitride materials, such as dielectric nitride materials and metal nitride materials. The etching chemistries and methods incorporate using an ultra-dilute (approximately 1500:1 to 2500:1) 49% hydrofluoric (HF) acid and optionally adding ozone (O₃) to the etching mixture that etches nitride materials selective to oxide materials, such as oxides doped with impurities or non-doped oxides, and resist patterning materials. The dilution of the HF acid will affect the selectivity of the etching solution (nitride material to the oxide or resist materials) and can be tailored to obtain a desired etching result.

### BRIEF DESCRIPTION OF THE DRAWINGS

FIG. 1 is a cross-sectional view of a semiconductor substrate section showing a patterned nitride layer lying between shallow trench isolation structures.

FIG. 2 is a subsequent cross-sectional view taken from FIG. 1 after the removal of the patterned nitride layer.

FIG. 3 is a cross-sectional view of a semiconductor substrate section after the formation of transistor structures.

FIG. 4 is a subsequent cross-sectional view taken from FIG. 3 having conductive plugs connected to source/drain regions of the transistors following by an opening formed in an overlying insulating material patterned by photoresist.

FIG. 5 is a subsequent cross-sectional view taken from FIG. 4 following an etch to deepen the opening and to expose the underlying transistor nitride spacers.

FIG. 6 is a subsequent cross-sectional view taken from FIG. 4 following an etch to pull back the exposed corners of the transistor nitride spacers.

FIG. 7 is a subsequent cross-sectional view taken from FIG. 6 following the formation of a conductive material into the opening, the conductive material making contact to the underlying conductive plug.

FIG. 8 is a simplified block diagram of a semiconductor system comprising a processor and memory device to which the present invention may be applied.

### DETAILED DESCRIPTION OF THE INVENTION

In the following description, the terms “wafer” and “substrate” are to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in or over the base semiconductor structure or foundation. In addition, the semiconductor need not be silicon-based, but could be based on silicon-germanium, silicon-on-insulator, silicon-on-saphire, germanium, or gallium arsenide, among others.

While the concepts of the present invention are conducive to selective etching of nitride materials used to form word lines, digit lines, trench isolation structures and structures having metal nitrides in semiconductor devices, such as memory devices, the concepts taught herein may be applied to other semiconductor processes that would likewise benefit from the use of the process disclosed herein. Therefore, the depiction of the present invention in reference to selective etching of nitride materials used to form word lines, digit lines, trench isolation structures and structures having metal nitrides for semiconductor devices, such as memory devices, is not meant to so limit the extent to which one skilled in the art may apply the concepts taught hereinafter.

The following exemplary implementations are in reference to methods for etching nitride materials with selectivity to oxide materials. The etching chemistry solution comprises an ultra-dilute hydrofluoric acid (starting with 49% HF prior to dilution) and the optional use of ozone (O₃), depending on the type of tool used to administer the etching chemistry as outlined below. Hereinafter, the reference to HF is to be considered 49% HF, prior to fuirther dilution.

There are a several ways to run a process using an ultra-dilute hydrofluoric acid. It is preferred the dilution ratio of the HF be 2000:1, but dilution ratios ranging from 1500:1 to 3000:1 are workable as well, depending on the desired results. In this process dilution ratio drives selectivity, and the temperature drives the etch rate. The ultra-dilute hydrofluoric acid can dispersed in a spray tool with O₃ (Condition A), dispersed in a spray tool without O₃, (Condition B) or in an immersion tank without O₃ (Condition C).

Taking condition (A), the etchant is dispersed in spray tool using various dilution ratios of HF ranging from 1500:1 to 3000:1 (2000:1 HF is preferred) along with O₃. Table 1 show the resulting etching rates for various oxide and nitride films using three dilutions of HF, namely 1500:1 HF, 2000:1 HF and 2500:1 HF. The diluted HF+O₃ solution, at a temperature of approximately 85° C., is presented to the various films, where the HF is fully dissociated. (Dissociation is where a chemical combination breaks up into simpler constituents: one that results from the action of energy (as heat) on a gas or of a solvent on a dissolved substance.) An example of using this method obtained the etching rates for the oxide and nitride films listed in Table 1.

TABLE 1
Condition (A) - Diluted HF (3-8 L/min) + O₃ (190-280 mg/l)

| | |
|---|---|
| 2500:1 | 2000:1 |

| | HF (85° C.) | HF (85° C.) | 1500:1 HF (85° C.) |
|---|---|---|---|
| Films | Etch Rate | Etch Rate | Etch Rate (Å/min) |
| | (Å/min) | (Å/min) | |
| Nitride 1 | 9.8 Å/min | 12.5 Å/min | 14.5 Å/min |
| Undoped Thermal | 0.1 Å/min | 0.2 Å/min | 0.4 Å/min |
| Oxide | | | |
| Nitride 2 | 10.2 Å/min | 13.1 Å/min | 15.2 Å/min |
| PSG Oxide | 0.0 Å/min | 1.4 Å/min | 3.9 Å/min |
| BPSG Oxide | 7.2 Å/min | 16.3 Å/min | 17.1 Å/min |
| (Annealed) | | | |
| Film A:Film B | Selectivity | Selectivity | Selectivity |
| Nitride 1:Undoped | ˜98:1 | ˜62.5:1 | ˜36:1 |
| Oxide | | | |
| Nitride 2:Doped | ˜102:1-1.4:1 | ˜9:1-0.8:1 | ˜3.9:1-0.9:1 |
| Oxide | | | |

As the etchant is presented to a wafer (or wafers) a very thin boundary exists between the wafer surface and the etchant. It is believed the thin boundary is basically maintained for the duration the etching sequence due to the HF being fully dissociated as the chemical comes in contact with the wafer. Also, it is believed that presenting a fully dissociated HF to the wafer surface is a major reason for restricting or even completely avoiding any significant etching of an oxide.

As seen from Table 1, the selectivity (the amount of nitride film that will be etched compared to the amount of oxide film that will be etched) can range from approximately 98:1 down to 36:1 for Nitride/Undoped Oxide, while the O₃ helps slow down the oxide etch, but speeds up the nitride etch. The selectivity is also good for Nitride/Doped Oxide and can range from approximately 102:1 down to 1:1 depending on the type of doped oxide. It is believed that using the etchant materials as outlined in condition (A) will also etch metal nitrides.

Taking the condition (B), the etchant is dispersed in spray tool with a dilution ratio of 2000:1 HF, at a temperature of approximately 85° C., where the HF is fully dissociated. The etchant is presented to a wafer(s) where a very thin boundary layer per wafer is present.

As seen in Table 2 below, selectivity can range from approximately 85:1 to 34:1 for Nitride 1/Undoped Oxide. Selectivity for Nitride/Doped Oxide can range from approximately from 11:1 to 1.0.7 depending on the type of doped oxide.

TABLE 2
Condition (B) - Diluted HF (3-8 L/min)

| | |
|---|---|
| 2500:1 | 2000:1 |

| | HF (85° C.) | HF (85° C.) | 1500:1 HF (85° C.) |
|---|---|---|---|
| Films | Etch Rate | Etch Rate | Etch Rate (Å/min) |
| | (Å/min) | (Å/min) | |
| Nitride 1 | 8.5 Å/min | 11.5 Å/min | 13.4 Å/min |
| Undoped Thermal | 0.1 Å/min | 0.2 Å/min | 0.4 Å/min |
| Oxide | | | |
| Nitride 2 | 8.9 Å/min | 12.1 Å/min | 14.1 Å/min |
| PSG Oxide | 0.8 Å/min | 1.2 Å/min | 2.7 Å/min |
| PSG Oxide | 4.4 Å/min | 23.8 Å/min | 21.4 Å/min |
| (Annealed) | | | |
| Film A:Film B | Selectivity | Selectivity | Selectivity |
| Nitride 1/Undoped | 85:1 | 57.5:1 | 33.5:1 |
| Thermal Oxide | | | |
| Nitride 2/Doped | 11.1:1-2.0:1 | 10.8:1-0.5:1 | 5.2:1-0.7:1 |
| Oxide | | | |

Taking the condition (C), where the etchant is in an immersion bath with a dilution ratio of 2000:1 HF, at a temperature of approximately 85° C., where the HF is fully dissociated and the etchant is presented to a wafer(or wafers) by immersing the wafer into an immersion tank containing the etchant, the results are presented in Table 3.

TABLE 3
Condition (C) - Diluted HF in Immersion Tank

| | 2500:1 HF (85° C.) | 2000:1 HF (85° C.) |
|---|---|---|
| Films | Etch Rate (Å/min) | Etch Rate (Å/min) |
| Nitride 1 | 8.98 Å/min | 8.7 Å/min |
| Undoped Thermal Oxide | 0.39 Å/min | 0.34 Å/min |
| Nitride 2 | 9.06 Å/min | 8.61 Å/min |
| PSG Oxide | 1.88 Å/min | 2.72 Å/min |
| BPSG Oxide (Annealed) | 18.01 Å/min | 19.85 Å/min |
| Film A:Film B | Selectivity | Selectivity |
| Nitride 1/Undoped | 23:1 | 25.6:1 |
| thermal Oxide | | |
| Nitride 2/Doped Oxide | 4.8:1-0.5:1 | 3.2:1-0.4:1 |

As can be seen from the above Tables 1-3, the etching chemistry mixture using 49% HF, etching duration and etching temperature can be tailored for the etching of a nitride material selective to specific oxide materials. As Tables 1-3 demonstrate, the HF dilution ratio drives etch selectivity, while the temperature drives the etch rate. This etching chemistry provides improved etching selectivity to doped oxides and un-doped oxides than can the use of conventional hot phosphoric acid etching chemistries. The etching chemistries of the present invention (specifically Conditions A, B and C) may also be tailored to etch metal nitrides, as it is known that ozone will etch metal and with the combination of a dilute HF to etch nitrides, this chemistry should also etch metal nitrides. Also, the etching chemistries of Conditions B and C allow for the patterning of nitride with certain resist (such as photoresist 44) as the nitride will be removed, thus leaving a substantial majority of the resist intact. It is further noted that Condition B will provide more nitride to resist selectivity than condition C.

Selectivity can range from 23:1 to 25:6 for Nitride 1/Undoped Oxide and selectivity will be good for Nitride/Doped Oxide and can range from 4.8:1 to 3.2:1 for PSG doped oxide, but be reduced to 0.5:1 to 0.4:1 for BPSG doped oxide. However, this etching condition will not etch metal nitrides.

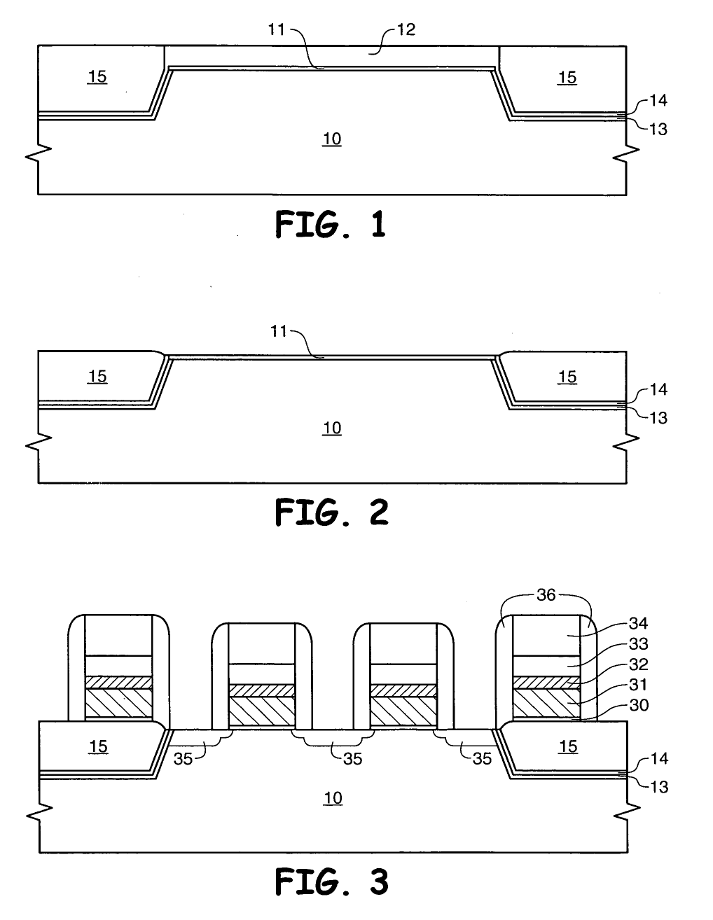

FIGS. 1-7 demonstrate examples of direct applications of the etching chemistry of the present invention in a semiconductor fabrication process. Referring now to FIG. 1, a semiconductor assembly, such as silicon wafer, is processed to the point where a silicon substrate 10 is covered with pad oxide 11 and patterned with nitride 12 prior to the formation of shallow trench isolation (STI) oxide 13, STI nitride 14 and high density plasma (HDP) oxide 15.

Referring now to FIG. 2, the assembly of FIG. 1 is subjected to an etching chemistry as developed in the present invention to completely remove nitride 12 while avoiding any significant reduction of HDP oxide 15.

For example, to remove nitride 12, an etching chemistry mixture of ozone and ultra-dilute hydrofluoric acid with a dilution of around 2000:1, maintained at a temperature of approximately 85° C., the selectivity for etching the nitride to HDP oxide 15 is around 45:1. This etch allows significant control that insures complete removal of nitride 12 while avoiding any significant reduction of HDP oxide 15 which is the main component for forming the shallow trench isolation structure.

Referring now to FIG. 3, the semiconductor assembly is processed by fabrication methods known to one of ordinary skill in the art to form transistor structures made up of transistor gates comprising gate oxide 30, insitu polysilicon 31, tungsten nitride (WNi) 32, tungsten 33, nitride cap 34 and nitride spacers 36. Source/drain implant regions 35 span between the gates. FIG. 3 represents typical field effect transistor formation. However, many types of conductors and dielectric can be and have been used to form transistors.

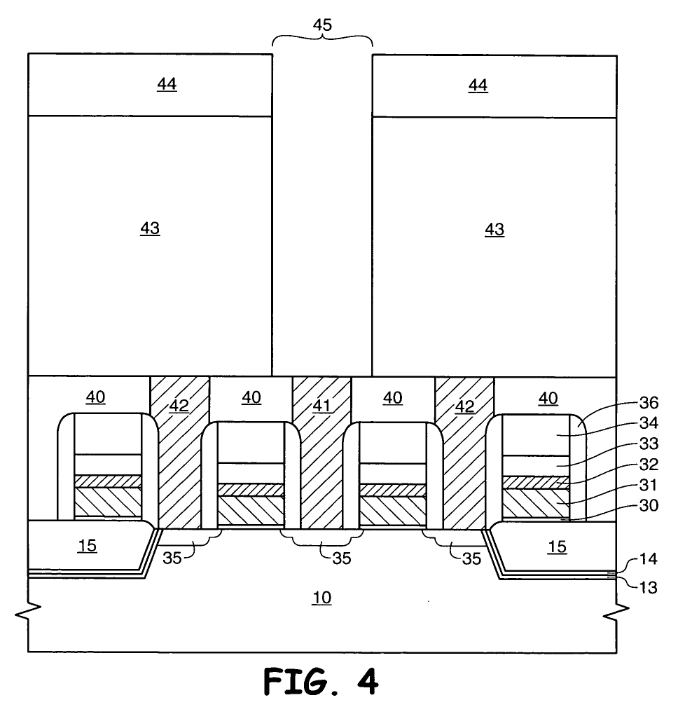

Referring now to FIG. 4, the semiconductor assembly is further processed by fabrication methods known to one of ordinary skill in the art to form a transistor isolation material 40, such as borophosphosilicate gate (BPSG) is formed over the transistor structures. Conductive plugs 41 and 42, made from materials such as polysilicon, are formed in an opening (or via) through the BPSG 40 and connect to an underlying source/drain region 35 of a respective transistor. The polysilicon plugs 41 and 42 and the BPSG 40 is planarized and a second isolation material 43 is formed on the planarized surface of polysilicon plugs 41 and 42 and the BPSG. Photoresist 44 is patterned over BPSG 43 and an etch is preformed to create opening 45 into BPSG 43 and thus exposes polysilicon plug 41.

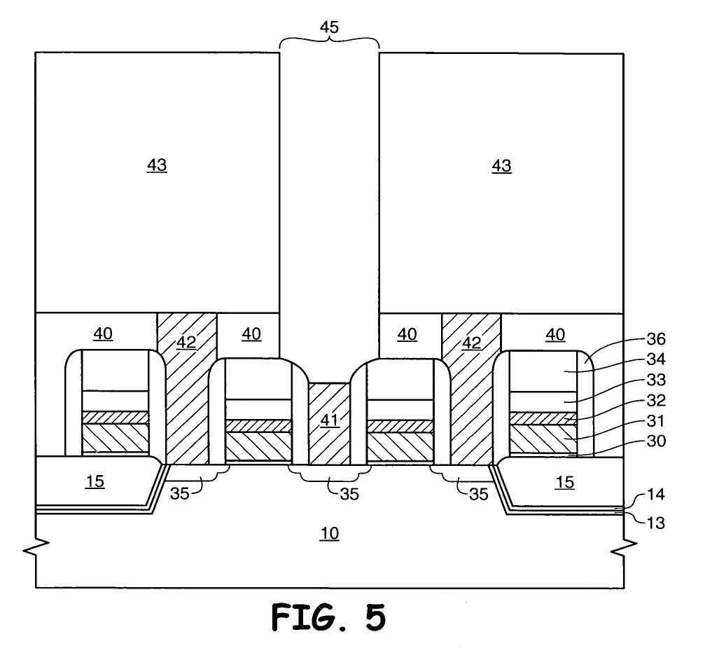

Referring now to FIG. 5, a second etch (or etches), know to one of ordinary skill in the art, is preformed to continue opening 45 until nitride spacers 36 are exposed and a portion of polysilicon plug 41 is reduced in height. It is at this point that a second application of the etching chemistry of the present invention is employed.

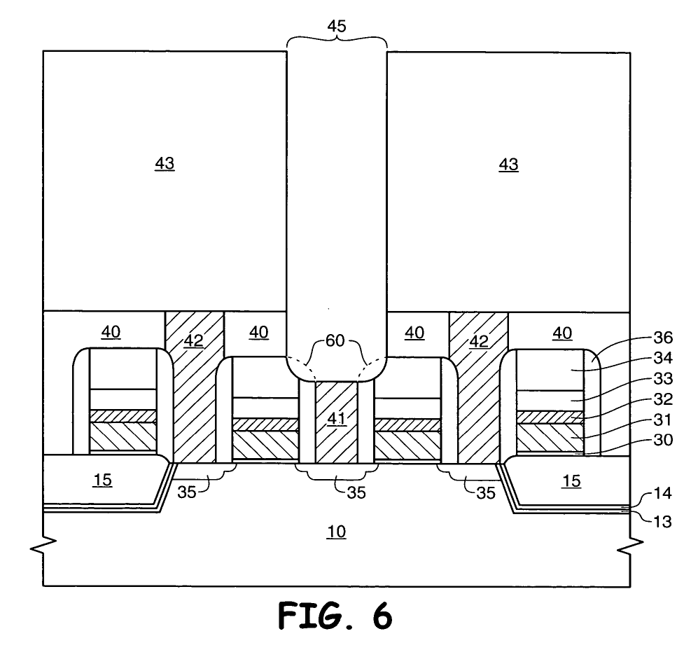

Referring now to FIG. 6, an etching chemistry mixture of ozone and ultra-dilute hydrofluoric acid with a dilution of around 2000:1, maintained at a temperature of approximately 75° C., the selectivity for etching the nitride corners 60 of nitride 35 to BPSG oxides 40 and 43 is around 45:1. This etch allows significant control to pull back the nitride corners 60 while avoiding any significant reduction of BPSG oxides 40 and 43.

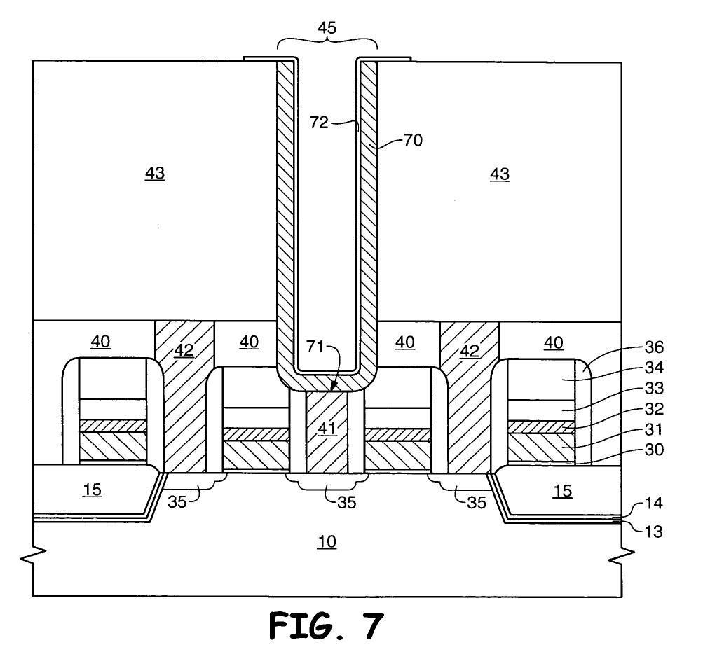

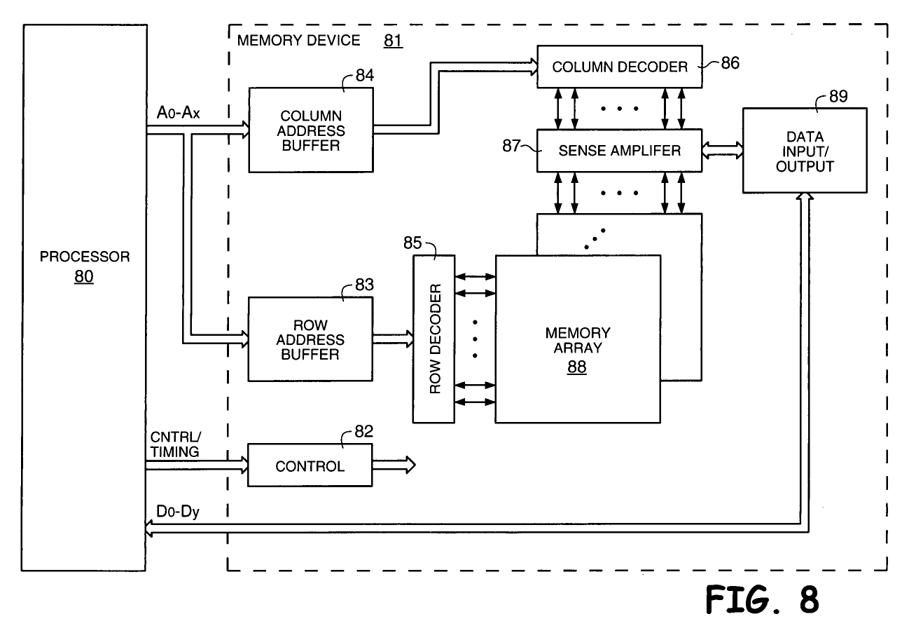

Referring now to FIG. 7, a conductive material 70, such as conductively doped polysilicon (i.e., hemispherical grained silicon) is formed into opening 45 and makes physical connection along contact region 71 to underlying polysilicon plug 41. The etch described from FIG. 6 avoids a nitride under etch and thus removes the nitride corners 60 and allows for a maximum contact surface area for contact region 71. In this example, polysilicon 70 will function as the storage plate of a capacitor and having maximum contact surface area for contact region 71 which will insure a reduced contact resistance between the polysilicon plug and the storage plate of a memory cell, thus allowing the memory cell to be functional.

The exemplary embodiments of the present invention have been discussed in reference to etching nitride materials with an etching chemistry that is selective to oxide materials in semiconductor assemblies, such as memory devices. However, the concepts taught in the exemplary embodiments, may be utilized by one of ordinary skill in the art use in most all semiconductor applications. For example, the present invention may be applied to a semiconductor system, such as the one depicted in FIG. 8, the general operation of which is known to one skilled in the art.

FIG. 8 represents a general block diagram of a semiconductor system comprising a processor 80 and a memory device 81 showing the basic sections of a memory integrated circuit, such as row and column address buffers, 83 and 84, row and column decoders, 85 and 86, sense amplifiers 87, memory array 88 and data input/output 89, which are manipulated by control/timing signals from the processor through control 82.

It is to be understood that, although the present invention has been described with reference to the exemplary embodiments, various modifications, known to those skilled in the art, may be made to the disclosed process herein without departing from the invention as recited in the several claims appended hereto.

What is claimed is:

1. An etching chemistry for removing a nitride material selective to an undoped oxide material for a semiconductor fabrication process comprising:
fully dissociated 49% hydrofluoric acid with a dilution of around 1500:1 to 2500:1.

2. The etching chemistry of claim 1, further comprising an etching temperature of around 85° C.

3. The etching chemistry of claim 1, further comprising an etching selectivity of the nitride to un-doped oxide at around 85:1 to 33.5:1.

4. The etching chemistry of claim 1, further comprising an etching selectivity of the nitride to doped oxide at around 11.1:1.

5. The etching chemistry of claim 1, further comprising ozone.

6. The etching chemistry of claim 5, further comprising an etching selectivity of the nitride to doped oxide up to around 102:1.

7. The etching chemistry of claim 5, further comprising an etching selectivity of the nitride to un-doped oxide at around 98:1 to 36:1.

8. An etching chemistry for removing a nitride material selective to a resist patterning material for a semiconductor fabrication process comprising:
fully dissociated 49% hydrofluoric acid with a dilution of around 1500:1 to 2500:1.

9. The etching chemistry of claim 8, further comprising an etching temperature of around 85° C.

10. The etching chemistry of claim 8, further comprising ozone.

11. An etching chemistry for removing a metal nitride material for a semiconductor fabrication process comprising:
fully dissociated 49% hydrofluoric acid with a dilution of around 1500:1 to 2500:1.

12. The etching chemistry of claim 11, further comprising an etching temperature of around 85° C.

13. The etching chemistry of claim 11, further comprising ozone.

14. A method for etching nitride material selective to an undoped oxide material in a semiconductor fabrication process comprising:
dispersing in an etchant spray tool an etchant comprising a fully dissociated 49% hydrofluoric acid, that is further diluted with water, to a semiconductor substrate having the nitride material and undoped oxide material thereon;
wherein the further dilution of the hydrofluoric acid is tailored such that a majority of the nitride material is removed while a minimal amount of the undoped oxide material is removed.

15. The etching chemistry of claim 14, further comprising an etching temperature of around 85° C.

16. The method of claim 14, wherein the further diluted with water is a dilution of ranges from around 1500:1 to 2500:1.

17. The method of claim 14, wherein the further diluted with water is a dilution of around 2000:1.

18. The method of claim 14, wherein the etchant further comprises ozone.

19. A method for etching nitride material selective to a doped oxide material in a semiconductor fabrication process comprising:
dispersing in an etchant spray tool an etchant comprising a fully dissociated 49% hydrofluoric acid, that is further diluted with water, to a semiconductor substrate having the nitride material and doped oxide material thereon;
wherein the further dilution of the hydrofluoric acid is tailored such that a majority of the nitride material is removed while a minimal amount of the doped oxide material is removed.

20. The etching chemistry of claim 19, further comprising an etching temperature of around 85° C.

21. The method of claim 19, wherein the further diluted with water is a dilution of ranges from around 1500:1 to 2500:1.

22. The method of claim 19, wherein the further diluted with water is a dilution of around 2000:1.

23. A method for etching nitride material selective to an undoped oxide material in a semiconductor fabrication process comprising:
placing a semiconductor substrate having the nitride material and undoped oxide material thereon in an etchant bath containing an etchant comprising a fully dissociated 49% hydrofluoric acid, that is further diluted with water;
wherein the further dilution of the hydrofluoric acid is tailored such that a majority of the nitride material is removed while a minimal amount of the undoped oxide material is removed.

24. The etching chemistry of claim 23, further comprising an etching temperature of around 85° C.

25. The method of claim 23, wherein the further diluted with water is a dilution of ranges from around 1500:1 to 2500:1.

26. The method of claim 23, wherein the further diluted with water is a dilution of around 2000:1.

27. A method for etching nitride material selective to a doped oxide material in a semiconductor fabrication process comprising:
placing a semiconductor substrate having the nitride material and undoped oxide material thereon in an etchant bath containing an etchant comprising a fully dissociated 49% hydrofluoric acid, that is further diluted with water;
wherein the further dilution of the hydrofluoric acid is tailored such that a majority of the nitride material is removed while a minimal amount of the doped oxide material is removed.

28. The etching chemistry of claim 27, further comprising an etching temperature of around 85° C.

29. The method of claim 27, wherein the further diluted with water is a dilution of ranges from around 1500:1 to 2500:1.

30. The method of claim 27, wherein the further diluted with water is a dilution of around 2000:1.

31. A method for etching a nitride material selective to a resist patterning material in a semiconductor fabrication process comprising:
placing a semiconductor substrate having the resist patterning material overlaying the nitride material thereon, in an etchant bath containing an etchant comprising a fully dissociated 49% hydrofluoric acid, that is further diluted with water;
wherein the further dilution of the hydrofluoric acid is tailored such that a majority of the nitride material is removed while a minimal amount of the resist patterning material is removed.

32. The etching chemistry of claim 31, further comprising an etching temperature of around 85° C.

33. The method of claim 31, wherein the further diluted with water is a dilution of ranges from around 1500:1 to 2500:1.

34. A method for etching metal nitride material in a semiconductor fabrication process comprising:
dispersing in an etchant spray tool an etchant comprising ozone and a fully dissociated 49% hydrofluoric acid, that is further diluted with water, to a semiconductor substrate having the metal nitride material thereon;
wherein the further dilution of the hydrofluoric acid is tailored such that the metal nitride material is removed.

35. The etching chemistry of claim 34, further comprising an etching temperature of around 85° C.

36. The method of claim 34, wherein the further diluted with water is a dilution of ranges from around 1500:1 to 2500:1.
